(19) United States
(12) Patent Application Publication
(10) Pub. No.: US 2006/0291161 A1
(43) Pub. Date: Dec. 28, 2006

(54) Heat dissipating surface for a portable device

(76) Inventors: Phi Tran, Dix Hills, NY (US); Eugene Romano, Brentwood, NY (US)

Correspondence Address: Phi Tran, 1020 Commack Rd., Dix Hills, NY, 11746, US

(21) Appl. No.: 11/174,266

(22) Filed: Jun. 28, 2005

(51) Int. Cl. H05K 7/20

(52) U.S. Cl. 361/688; 361/687

(57) ABSTRACT

A device provides a surface on which a portable device, especially laptop computers, can be placed for heat dissipation. This device will act as a shield for the bottom of the portable device. The device will be made of two layers. One layer will dissipate heat from the portable device and the other layer will dissipate heat from the user. The device provides users comfort and protection from heat generated by the portable device.

### CROSS-REFERENCE TO RELATED APPLICATIONS

Not Applicable

### FEDERALLY SPONSORED RESEARCH

Not Applicable

### SEQUENCE LISTING OR PROGRAM

Not Applicable

### BACKGROUND OF THE INVENTION

1. Field of Invention

This invention relates to an external cooling device for portable devices and cases for electronic devices.

2. Background of the Invention

Portable devices, especially laptops, are extremely popular for users who travel frequently or who need to take their device to a work site or for personal entertainment. To enhance their portability, these devices are designed to be lightweight and combine several electronic devices into a relatively small package.

Because of the density of electronics inside the device, a number of strategies have been used to provide adequate cooling to the components inside the device. This includes the use of heat pipes, radiator fins, and fans. However, the lower surfaces of these portable devices become quite hot during operation. If adequate ventilation to this surface is not provided, overheating of internal components and possible malfunctions may result. Additionally, if the user is using the portable device on their lap, it becomes uncomfortable to continue use.

There have been several inventions that address the problem of the heat generated within portable devices like laptops. So far the solutions noted below suffer from a number of disadvantages.

U.S. Pat. No. 5,969,939 to Moss (1999) is designed to cool the laptop while it is attached to a docking station, so that a surface of the laptop is in engagement with a heat conductive surface. The laptop is only cooled while using the docking station, giving the disadvantage of immobility. The docking station is intended for use on a table and not on a lap, sofa, bed, or while in transit. Also, heat transfer by conduction is only effective if the conductive surfaces are flush in tight contact with each other to aid thermal conduction from the laptop chassis to the surface.

U.S. Pat. No. 5,982,615 to Song (1999) attempts to increase heat loss through ventilation holes formed on the keyboard. This development requires a change in keyboard and also provides more apertures, which allows more dust to enter.

U.S. Pat. No. 5,936,836 to Scholder (1999) uses a fan to direct airflow over the heat sink in order to remove heat from the heat sink. The running of an extra fan draws on the battery power.

Several Patents such as U.S. Pat. No. 5,822,187 to Thermal Corp (1998), U.S. Pat. No. 5,910,883 to IBM (1999), U.S. Pat. No. 5,818,693 to Thermal Corp (1998), and U.S. Pat. No. 5,966,286 to O'Conner, use a system of heat pipes to cool the laptop. Other Patents such as DE 4244743 to Toshiba Kawasaki KK (1995), U.S. Pat. No. 5,634,351 to Aavid Lab Inc (1997), U.S. Pat. No. 5,606,341 to NCR Corp (1997), U.S. Pat. No. 5,826,643 to Gaylon (1998), and others, require the use of liquid coolants within the laptop to aid in heat loss. Each of these solutions require a system of ducts, pipes, or bags of flexible film that contain the coolant for evaporation and condensation. This requires specific incorporation inside the laptop. This reduces housing space in the laptop, which allows less space to be used for other components. These methods also add weight and may increase the size of the chassis.

U.S. Pat. No. 6,466,438 to Lim (2002) uses a corrugated sheet of material to give the laptop a given amount of breathing space for the laptop to cool. Corrugating a sheet gives minimal contact to the surface of the laptop and allows unobstructed airflow. This design is not universal because of different laptop chassis designs used. Many laptops have inconsistent bottom surfaces that cause difficulty in fitting a corrugated material to fit properly. Also, the method of corrugating a material requires more energy and is more difficult to achieve.

One commercially available cooling device uses a refrigerated product that is placed between the user and the laptop, which provides a cool barrier. A reusable cooling gel, similar to a medical ice pack, is refrigerated then put between the user and device. A product that needs to be refrigerated will not be long lasting or as mobile as the laptop.

Another commercially available device uses three layers to help protect the user from heat. The three layers are packaged together and wrap the laptop. This gives the laptop a bulky look, which affect the mobility and slim look of the laptop.

Several other commercial devices use a stand to help reduce heat contact to the user. Each of these stands achieve the affect of keeping the user and the laptop cool, but add bulkiness and give the disadvantage of mobility.

Nevertheless, all cooling devices heretofore known suffer from a number of disadvantages:
(a) Docking stations cannot be portable.
(b) Ventilation through keyboards require a change in keyboard manufacturing and allows more dust to enter.
(c) Fans that connect to the device use power from the device resulting in shorter energy life of the battery.
(d) Adding heat pipes or liquid coolants reduces housing space in the casing of the device that can be used for other components.
(e) A corrugated sheet is difficult to achieve and does not properly fit because of the inconsistent bottom surfaces of devices.
(f) Products that need refrigeration are not portable or long lasting.
(g) Wrapping the device adds bulkiness and adds more difficulty in portability.
(h) Using stands have a disadvantage of mobility, which defeats the purpose of portability.

There are many disadvantages to present inventions. Accordingly, there exists a need for a product that facilitates the improved flow of cool air under the portable device for cooling. There exists a need for a product that is lightweight, unnoticeable, and ideal for portability. There exists a need for a product that can match the technological advances in portable devices.

### BACKGROUND OF INVENTION—OBJECTS AND ADVANTAGES

Among the objects of the present invention are:
(a) To provide heat transfer from the device without requiring it to be attached to an immobile structure which in part defeats the purpose of mobility.
(b) To provide heat transfer from the device without the need for more apertures, thus decreasing the exposure of internal components to dust.
(c) To provide heat transfer from the device without the need to draw power from the main source or battery.
(d) To provide heat transfer from the device, without adding more apparatus or components to the limited space available within the casing, or adding extra weight to the device itself.
(e) To provide a more basic form which improves heat transfer from the device via the chassis, and allow a heated chassis to be comfortably used on a lap.
(f) To provide heat transfer from the device without requiring it to be refrigerated which in part defeats the purpose of mobility.
(g) To provide heat transfer or heat protection without extra external bulkiness and added weight to keep the device as mobile as it was meant to be.
(h) To provide a product that is slim and portable.

Further objects and advantages are to provide a cooling device, which can be easily and conveniently, used without internal alterations to the portable device itself.

### SUMMARY

In accordance with the present invention, a cooling device consists of two layers to dissipate heat. One layer will dissipate heat from the portable device. The other layer will dissipate heat from the user or work surface.

### DRAWINGS—FIGURES

In the drawings, closely related figures have the same number but different alphabetic suffixes.

FIG. 1A shows the preferred embodiment (side view).

FIG. 1B shows the preferred embodiment (bottom view).

FIG. 1C shows the preferred embodiment (isometric view).

FIG. 2 shows the preferred embodiment in use (side view).

FIG. 2B shows the preferred embodiment in use illustrating the transfer of radiant heat (close-up view).

FIG. 3A shows the dissipater attached to the base of the chassis.

FIG. 3B shows the attached dissipater in an open position.

FIG. 4A shows the dissipater with feet attached to the bottom.

FIG. 4B shows the dissipater with padding attached to the bottom.

FIG. 4C shows the dissipater with swivel base attached to the bottom.

FIG. 5A represents an additional embodiment of the invention, as two separate layers.

FIG. 5B represents an additional embodiment of the invention, as the top layer having a concave shape.

FIG. 5C represents an additional embodiment of the invention, as the two layers conformed into one piece.

FIG. 5D represents an additional embodiment of the invention, as a single layer.

FIG. 6A represents an additional embodiment of the invention, as applied to a desktop, server, or electronic device.

FIG. 6B represents an additional embodiment of the invention, as applied to a portable device.

DRAWINGS—Reference Numerals

| | | | |
|---|---|---|---|
| 10 | rounded corners | 12 | mount |
| 14 | anti slip | 16 | portable device |
| 17 | airflow | 18 | thermal radiation from device |
| 20 | thermal radiation from user | 22 | hinge |
| | or surface | | |
| 24 | clamp | 26 | access to base |
| 28 | feet | 30 | padding |
| 31 | swivel base | 32 | spacer |
| 34 | lip | 36 | concave form |
| 38 | hollow formation | 40 | invention applied to application |

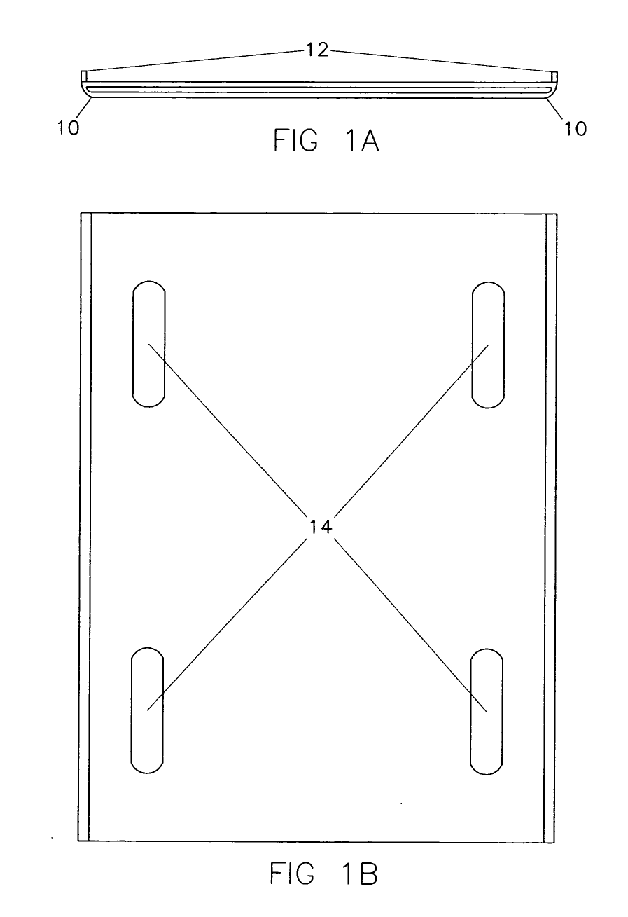

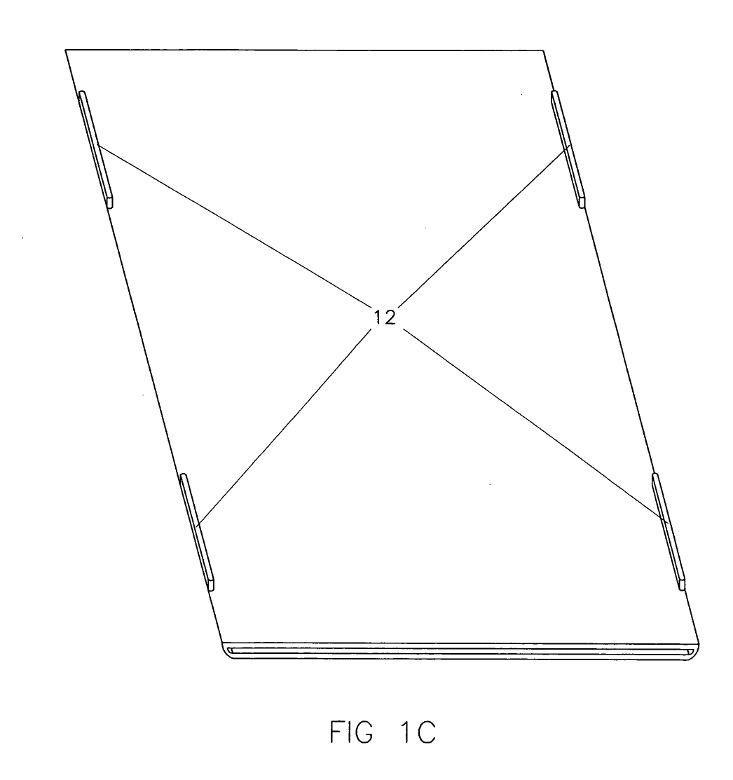

### DETAILED DESCRIPTION—FIGS. 1A-1C—PREFERRED EMBODIMENT

A preferred embodiment of the present invention is illustrated in FIG. 1A (side view), FIG. 1B (bottom view), and FIG. 1C (isometric view). The device comprises a sheet of material continuous in form to provide two layers, as shown in FIG. 1A. The device is made of a material with a high thermal conductivity and a high strength to weight ratio such as aluminum.

The preferred embodiment has a durable anti-corrosion finish. This finish can be achieved by an anodizing process, in which the sheet of material is used as the anode, an electrolysis process resulting in the formation of an even coat of an oxide layer over the surface. The color depends on the type of oxide used in the electrolysis.

The device may be manufactured in a range of sizes, adapted to the dimensions of the device being used, in a rectangular shape. The thickness of the sheet can vary.

As shown in FIG. 1A and FIG. 1C, the comers are rounded 10 to prevent personal injury from sharp comers. The mounts 12 are used to attach to the chassis. The attachment of the mounts 12 to the chassis can be achieved using hook-and-loop fasteners. If hook-and-loop fasteners are not wanted, optional anti slip products can be used. Mounts 12 are raised to compensate for added feet on the bottom of some chassis.

As shown in FIG. 1B, anti slip 14 product such as rubber is attached to the bottom to provide friction to the work surface. This prevents both the device and the cooling device from being knocked off the work surface by accident.

Operation—FIGS. 1-3

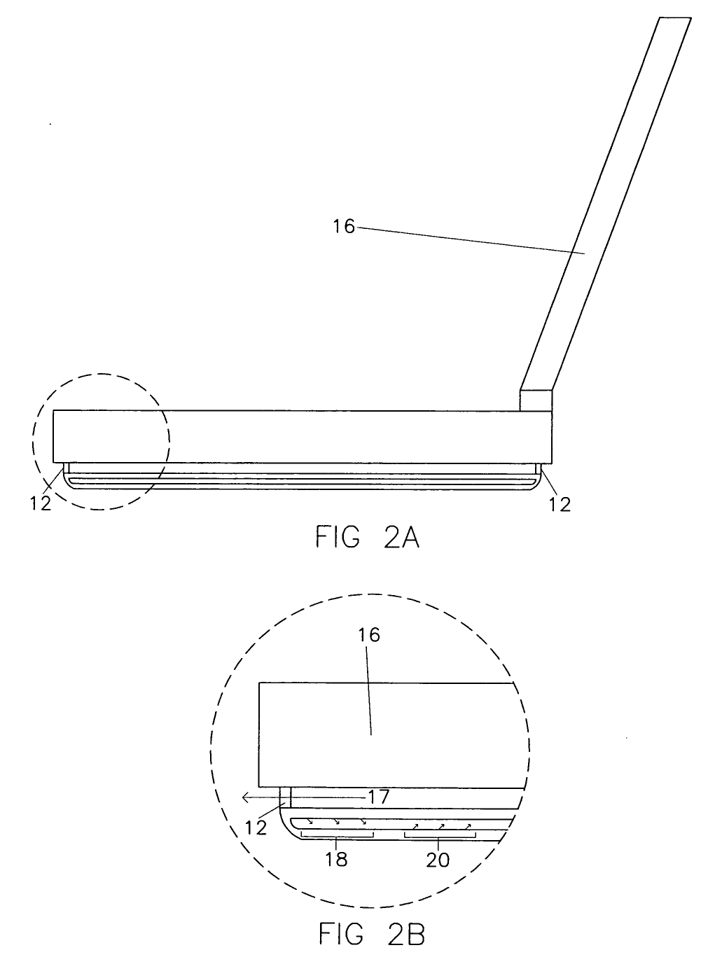

Operation of the preferred embodiment of the invention is illustrated in FIG. 2A (side view) and FIG. 2B (close-up view).

Center the portable device 16 on the cooling device and attach it at the mounts 12. Turn on the portable device.

As the portable device is used, internal components generate heat inside the portable device, not all of which escapes through vents. The heat builds up making the portable device a hotter body in relation to the cooling device. Therefore heat is transferred from the portable device to the cooling device. The cooling device heats up, becoming hotter than the environment and in turn transfers heat to the environment.

The surface of the cooling device provides efficient heat transfer by thermal radiation so it cools the portable device 16 by absorbing radiant heat from the portable device 18 emitting it to the environment. Heat is also transferred from a surface or user 20 and is emitted into the environment. Two layers of heat transfer minimize heat buildup between the portable device and the surface or user, which results in more effective cooling and protection. This is illustrated in FIG. 2B.

While the portable device sits on the mounts 12, contact between the portable device and the cooling device minimize blockage of any air vents to allow unobstructed airflow 17.

Thus, the cooling device reduces the problem of heat build up within the portable device because it acts as an intermediate work surface that dissipates radiant heat away from the portable device thereby cooling it, irrespective of the thermal properties of the actual work surface used.

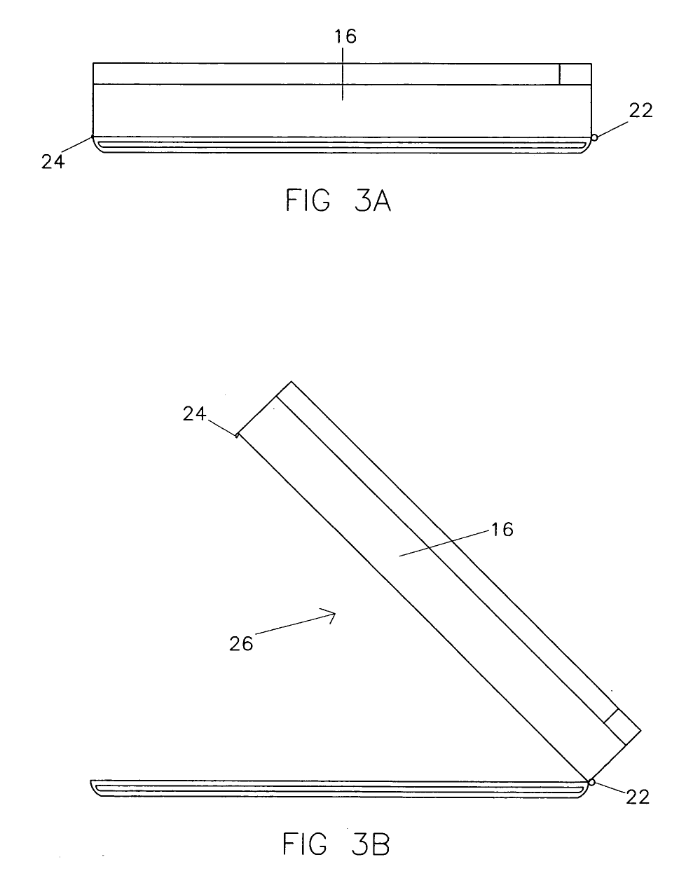

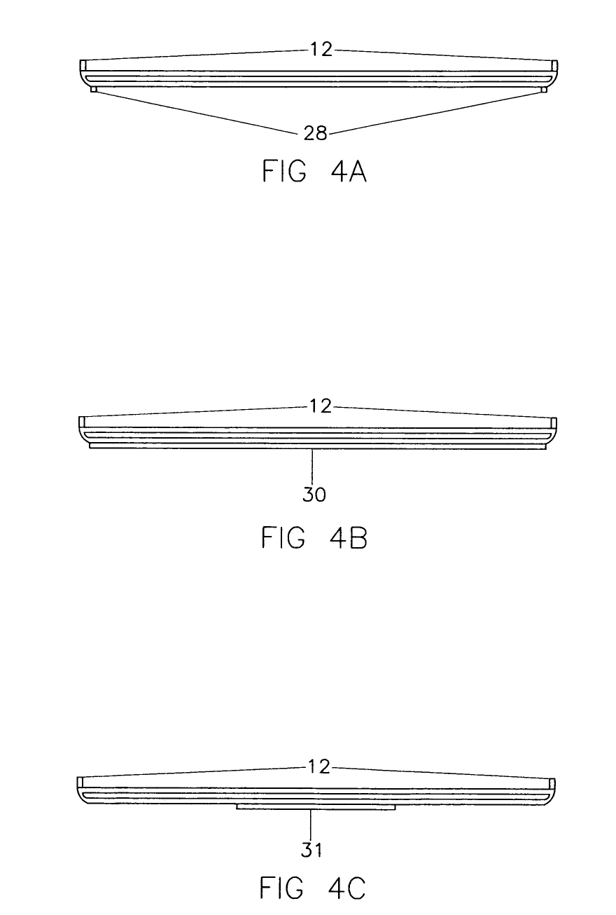

FIGS. 3-4—Additional Embodiments

Additional embodiments are shown in FIGS. 3A, 3B, 4A, 4B, 4C.

Manufacturers can attach the basic cooling device to the base of an external chassis as shown in FIG. 3A and FIG. 3B. Using attachments such as releasable clamps 24 and external hinge 22, the portable device may be easily moved for access 26 to internal components for upgrading or repair.

Other additional embodiments include attaching various applications to the bottom of the cooling device in FIG. 4.

FIG. 4A shows the cooling device with feet 28 attached to the bottom. The feet 28 can have anti slip to add friction to a work surface to prevent accidental slips and protect the work surface.

FIG. 4B shows the cooling device with padding 30 attached to the bottom. The padding 30 can be made of various materials from rubbers to plastic foams to provide comfort when setting the device on the user's lap.

FIG. 4C shows the cooling device with swivel base 31 attached to the bottom. The swivel base 31 can be in various radiuses. The swivel base 31 can have anti slip attached to the bottom to add friction to a work surface and help prevent accidental slips and protect the work surface.

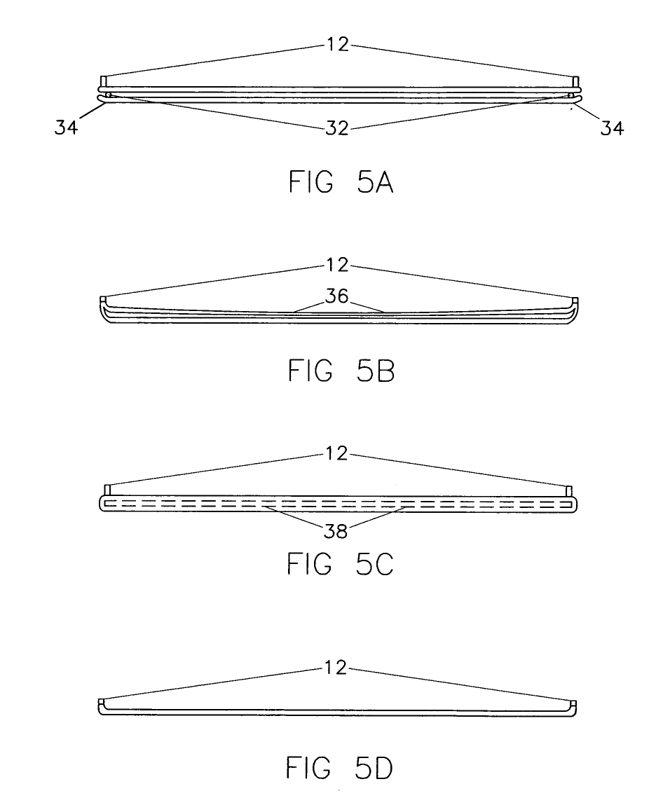

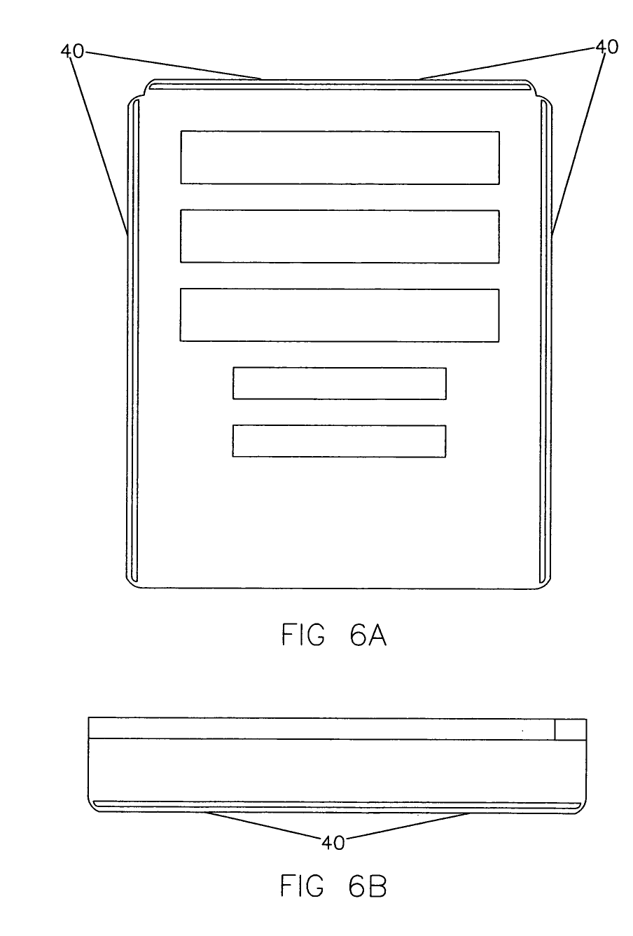

FIGS. 5-6—Alternative Embodiments

Alternative embodiments are shown in FIGS. 5A, 5B, 5C, 5D, 6A, 6B.

FIG. 5A shows the cooling device as two separate layers. Spacers 32 keeps the two layers separate. The bottom layer has lips 34 to minimize sharp edges to prevent personal injury and adds comfort when used on a user's lap.

FIG. 5B shows the cooling device having a concave top layer 36. This shows that the top layer does not have to be flat and creates the many different possibilities of forms the top layer may have.

FIG. 5C shows the cooling device as one piece. The inside of the device is hollow 38, technically having a top layer for the portable device and a bottom layer for the user or work surface.

FIG. 5D shows the cooling device as a single layer. The single layer has mounts 12 to create a space between the cooling device and the portable device.

In FIG. 6A, another alternative embodiment of the invention provides external cooling equipment for cooling cases which comprises a material adapted to fit around the casing of the unit. Having only contacting the casing over only a part thereof permits the free passage of air across the casing. The invention applied to the application 40 can be seen around the case.

FIG. 6B provides the invention to part of the casing, most likely a location generating the most heat. The invention applied to the application 40 is shown on the bottom of the casing.

Advantages

From the description above, a number of advantages of my cooling device become evident:
(a) The simplicity of design and manufacture results in relatively lower manufacturing costs.
(b) The protective coating makes the cooling more durable especially when it is in transit and is resistant to corrosion.
(c) The mounts reduce the risk of the device being knocked off the cooling device.
(d) The two layers formed from a continuous sheet provide heat dissipation from two sources of thermal radiation.
(e) The mounts ensure that contact with the device is such that blocking of any air vents is minimized.
(f) As it is designed to cool a portable device from below, the shape of the cooling tray does not obstruct any communication ports can and is therefore generic in use, requiring no alternation by the user so the operation of the cooling device is simple.
(g) Manufacturers can incorporate it into the base of the chasses for external integration by making relatively small modifications. This requires no modifications of internal components.
   Conclusion, Ramifications, and Scope

Accordingly the reader will see that the cooling device according to the invention is easy to use, and is suitable for any portable device. Its light and portable attributes make it a convenient way to cool a portable device. In addition it is simple for manufacturers to add on to the external chassis of their portable device without the need to alter or add to the internal components of the portable thereby reducing costs.

Furthermore the device has additional advantages in that:
Its basic form can be incorporated into a variety of applications in portable device accessories, which will then serve to cool the portable device while it is in use.
It allows for lower manufacturing costs due to its simple and generic design.
It allows for durability as its protective coating makes it resistant to corrosion.
It provides a safe work surface for laptops because of the anti slip attachments.
It provides comfortable prolonged use on a lap.

Although the description above contains many specificities, these should not be construed as limiting the scope of the invention but as merely proving illustrations of some of the presently preferred embodiments of this invention.

Thus the scope of the invention should be determined by the appended claims and their legal equivalents, rather than by the examples given.

I claim:

1. An autonomous, cooling device for use with a portable electronic device having a base comprising:
(a) a plurality of sheets of material and
(b) said sheets are layered with a void between said sheets whereby said sheets when in contact with said base provides cooling for said electronic device.

2. The autonomous, cooling device as in claim 1 wherein said sheets are a first sheet and a second sheet formed as a single, autonomous sheet of material forming an oblong annulus.

3. The autonomous, cooling device as in claim 2 wherein said first sheet have at least one elongated support member a at right angle to the top side of said first sheet.

4. The autonomous, cooling device as in claim 2 wherein said second sheet including at least one oblate anti slip member, including at least one elongated support member at a right angle, including a material means for padding, or including a swivel base to the underside of said second sheet.

5. The autonomous, cooling device as in claim 1 wherein said sheets having a joint and a clamp in connection with said base of said electronic device.

6. The autonomous, cooling device as in claim 1 wherein said sheets are a first sheet and a second sheet joined by at least one member by means said first sheet is parallel to said second sheet.

7. The autonomous, cooling device as in claim 1 wherein said sheets are a first sheet and a second sheet joined at edge means forming a closed container.

8. The autonomous, cooling device as in claim 1 wherein said sheets are a first sheet be a non-plane formation.

9. The autonomous, cooling device as in claim 1 wherein said sheets is only a first sheet.

10. The autonomous, portable cooling device as in claim 1 wherein said sheets are material of high thermal conductivity as to provide rapid heat transfer.

11. A device for cooling a portable device comprising:
(a) a first sheet supporting said portable device and
(b) a second sheet is a layer under said first sheet with a void between said first sheet and said second sheet.
wherein said first sheet is adapted to receive said portable device means provides cooling for said portable device.

12. The device for cooling as in claim 11 wherein said first sheet and said second sheet formed as a single, autonomous sheet of material forming an oblong annulus.

13. The device for cooling as in claim 11 wherein said first sheet have at least one elongated support member at a right angle to the top side of said first sheet.

14. The device for cooling as in claim 11 wherein said second sheet including at least one oblate anti slip member, including at least one elongated support member at a right angle, including a material means for padding, or including a swivel base to the underside of said second sheet.

15. The device for cooling as in claim 11 wherein said first sheet having a joint and a clamp in connection with said portable device.

16. The device for cooling as in claim 11 wherein said first sheet and said second sheet joined by at least one member by means said first sheet is parallel to said second sheet.

17. The device for cooling as in claim 11 wherein said first sheet be a non-plane formation.

18. The device for cooling as in claim 11 wherein said second sheet is eliminated.

19. The device for cooling as in claim 11 wherein said sheets are material of high thermal conductivity as to provide rapid heat transfer.
